(19) United States
(12) Patent Application Publication
(10) Pub. No.: US 2014/0087138 A1
(43) Pub. Date: Mar. 27, 2014

(54) 3-DIMENSIONAL NANOPLASMONIC STRUCTURE AND METHOD OF MANUFACTURING THE SAME

(71) Applicant: SAMSUNG ELECTRONICS CO., LTD., Suwon-si (KR)

(72) Inventors: Ji-hyun BAE, Seoul (KR); Jong-jin PARK, Hwaseong-si (KR); Sang-hun JEON, Seoul (KR)

(73) Assignee: SAMSUNG ELECTRONICS CO., LTD., Suwon-si (KR)

(21) Appl. No.: 13/898,923

(22) Filed: May 21, 2013

(30) Foreign Application Priority Data
Sep. 24, 2012 (KR) 10-2012-0105953

(51) Int. Cl. G02F 1/01; C23C 14/14; C23C 14/22; C23C 14/58; C23C 16/56

(52) U.S. Cl. CPC G02F 1/01; C23C 14/5806; C23C 16/56; C23C 14/221; C23C 14/14
USPC 428/148; 427/123; 427/124; 427/597

(57) ABSTRACT

A three-dimensional (3D) nanoplasmonic structure includes a substrate; a plurality of nanorods formed on the substrate; and a plurality of metal nanoparticles formed on surfaces of the substrate and the plurality of nanorods. A method of manufacturing a 3D nanoplasmonic structure includes preparing a substrate; growing a plurality of nanorods on the substrate; forming a metal layer on surfaces of the plurality of nanorods; and dewetting the metal layer into particles by heat-treating the metal layer

### CROSS-REFERENCE TO RELATED APPLICATION

This application claims priority from Korean Patent Application No. 10-2012-0105953, filed on Sep. 24, 2012 in the Korean Intellectual Property Office, the disclosure of which is incorporated by reference herein in its entirety.

### BACKGROUND

1. Field

The present disclosure relates to three-dimensional (3D) nanoplasmonic structures and methods of manufacturing the same.

2. Description of the Related Art

A plasmonic effect is an optoelectronic effect occurring in a metal and is a phenomenon in which free electrons in a metal collectively oscillate due to external light. Such an effect occurs as the result of a resonance phenomenon in which most of the light energy of incident light having a certain wavelength is shifted to free electrons.

The resonance phenomenon occurs between a metal having a negative dielectric constant and a high conductivity and a general insulator material having a positive dielectric constant. When the frequency of incident light equals the natural frequency of the surface plasmon of a metal, most of the incident light is absorbed.

With regard to metal nanoparticles, the electric field of visible light or near-infrared light may be paired with a plasmon to cause light absorption, thereby achieving a vivid color.

The above phenomenon is referred to as surface plasmon resonance and locally forms a locally highly increased electric field, which means that light energy is transformed by a surface plasmon and is accumulated on the surfaces of metal nanoparticles. This also permits optical control in a region smaller than the diffraction limit of light.

Metal nanoparticles strongly and distinctively interact with an electromagnetic wave due to, for example, the surface plasmon resonance phenomenon, and thus the light absorption band may be amplified and controlled. Accordingly, metal nanoparticles are expected to be used in various fields, including fluorescence spectroscopy, various sensors, and optoelectronic devices.

### SUMMARY

Embodiments provide 3-Dnanoplasmonic structures and methods of manufacturing the same.

According to an aspect of an embodiment, there is provided a 3-D nanoplasmonic structure including a substrate; a plurality of nanorods formed on the substrate; and a plurality of metal nanoparticles formed on surfaces of the substrate and the plurality of nanorods.

The plurality of nanorods may be formed from an oxide semiconductor material, a metal oxide, an insulating material, or carbon nanotubes.

The plurality of metal nanoparticles may include one of gold (Au), silver (Ag), ruthenium (Ru), and copper (Cu).

The plurality of metal nanoparticles may have a size distribution of at least two sizes.

The substrate may be a textile structure and may include, for example, a textile fiber and a conductive layer coated on a surface of the textile fiber.

The substrate may include a carbon material textile or an inorganic material textile.

According to an aspect of another embodiment, there is provided an optoelectronic device includes the above 3-D nanoplasmonic structure.

According to an aspect of another embodiment, there is provided a method of manufacturing a 3-D nanoplasmonic structure, the method including preparing a substrate; growing a plurality of nanorods on the substrate; forming a metal layer on surfaces of the plurality of nanorods; and dewetting the metal layer into particles by heat-treating the metal layer.

The plurality of nanorods may be formed from an oxide semiconductor material, a metal oxide, an insulating material, or carbon nanotubes.

The growing of the plurality of nanorods may be performed using a chemical vapor deposition (CVD) method or a hydrothermal method.

The metal layer may include one of gold (Au), silver (Ag), ruthenium (Ru), and copper (Cu).

The forming of the metal layer may be performed using an electron beam (e-beam) deposition method, a thermal deposition method, an atomic layer deposition (ALD) method, or a sputtering method.

The forming of the metal layer may include forming the metal layer to have a thickness of from about 10 nm to about 100 nm.

The dewetting temperature may be from about 350° C. to about 700° C.

The dewetting time may be from about 1 hour to about 5 hours.

The substrate may be a textile structure and may include, for example, a textile fiber and a conductive layer coated on a surface of the textile fiber.

The substrate may include a carbon material textile or an inorganic material textile.

According to an aspect of another embodiment, there is provided a method of adjusting a surface plasmon resonance frequency, the method including forming a surface plasmon resonance structure; and dewetting a metal material included in the surface plasmon resonance structure.

The surface plasmon resonance structure may include a plurality of nanorods and a metal layer formed on at least one surface of the plurality of nanorods.

The metal layer may have a thickness of from about 10 nm to about 100 nm.

A dewetting temperature of the dewetting may be from about 350° C. to about 700° C.

A dewetting time of the dewetting may be from about 1 hour to about 5 hours.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view of a 3-D nanoplasmonic structure according to an embodiment;

FIG. 2 is a diagram illustrating a dewetting process used in a method of manufacturing a 3D nanoplasmonic structure, according to an embodiment;

FIGS. 3A through 3E are diagrams illustrating a method of manufacturing a 3D nanoplasmonic structure, according to an embodiment;

FIGS. 4A and 4B are microscopic images of a plurality of nanorods and a plurality of metal nanoparticles, respectively, formed using a method of manufacturing a 3D nanoplasmonic structure, according to an embodiment;

FIGS. 5A and 5B are graphs showing size distributions of metal nanoparticles formed according to a method of manufacturing a 3D nanoplasmonic structure, according to an embodiment; and

FIGS. 6A and 6B are graphs showing absorbance spectra before and after heat treatment is performed in a method of manufacturing a 3D nanoplasmonic structure, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, expressions such as “at least one of,” when preceding a list of elements, modify the entire list of elements and do not modify the individual elements of the list.

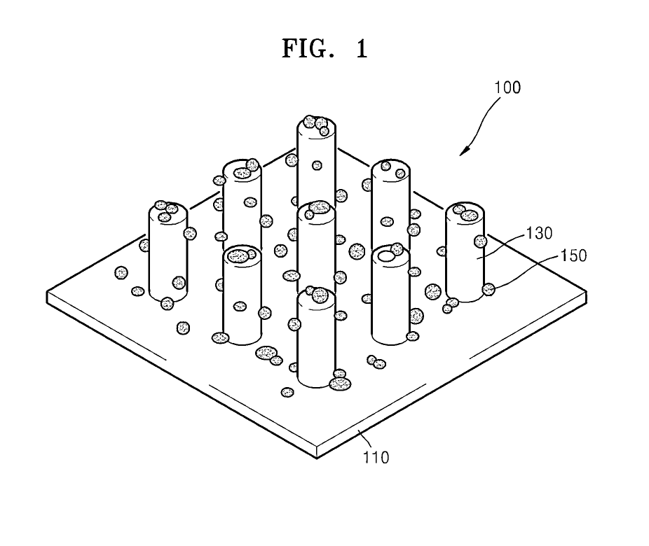

FIG. 1 is a perspective view of a 3D nanoplasmonic structure 100 according to an embodiment.

The 3D nanoplasmonic structure 100 includes a substrate 110, a plurality of nanorods 130 formed on the substrate 110, and a plurality of metal nanoparticles 150 formed on surfaces of the substrate 110 and the nanorods 130.

The substrate 110 may be a substrate formed from various materials on which the nanorods 130 can be formed. For example, a semiconductor substrate formed from silicon (Si), germanium (Ge), GaAs, or GaN; a polymer substrate formed from an organic polymer or an inorganic polymer; or a substrate formed from quartz or glass may be used. Also, a textile structure having a large specific surface area may be used as a substrate. The textile structure substrate may be flexible and may include a textile fiber and a conductive layer coated on a surface of the textile fiber. Alternatively, the substrate 110 may have a carbon material textile structure or an inorganic material textile structure.

The nanorods 130 may be formed from an oxide semiconductor material, a metal oxide, an insulating material, or carbon nanotubes. For example, the nanorods 130 may include one of ZnO, In₂O₃, Ga₂O₃, SnO, In-Zn oxide (IZO), In-Tin oxide (ITO), Ga—In—Zn oxide (GIZO), HflnZnO, SnO₂, Co₃O₄, Mn₃O₄, MnO, Fe₂O₃, Fe₃O₄, NiO, MoO₃, MoO₂, TiO₂, CuO, Cu₂O, LiFePO₄, CeO₂, RuO₂, MnO₂, Li₄Ti₅O₁₂, and Li₃V₂(PO₄)₃, and may be in the form of nanowires or nanotubes.

The metal nanoparticles 150 are present and may be formed on at least one surface of the nanorods 130 and may be formed on the surface of the substrate 110. The metal nanoparticles 150 may include at least one of gold (Au), silver (Ag), ruthenium (Ru), and copper (Cu). The metal nanoparticles 150 may not have a uniform size and may have a size distribution of at least two sizes.

The above 3D nanoplasmonic structure 100 has an increased active region as compared to a two-dimensional (2D) or one-dimensional (1D) structure because the metal nanoparticles 150 are three-dimensionally distributed along the surfaces of the nanorods 130. Further, the 3D nanoplasmonic structure may be used in various optoelectronic devices, such as biosensors, light-emitting devices, and energy storing devices, such as solar batteries or secondary batteries because the plasmonic effect provides for a high optical absorption rate and because the absorbance wavelength band may be adjusted.

A dewetting process is used in the current embodiment to form the above 3D nanoplasmonic structure 100.

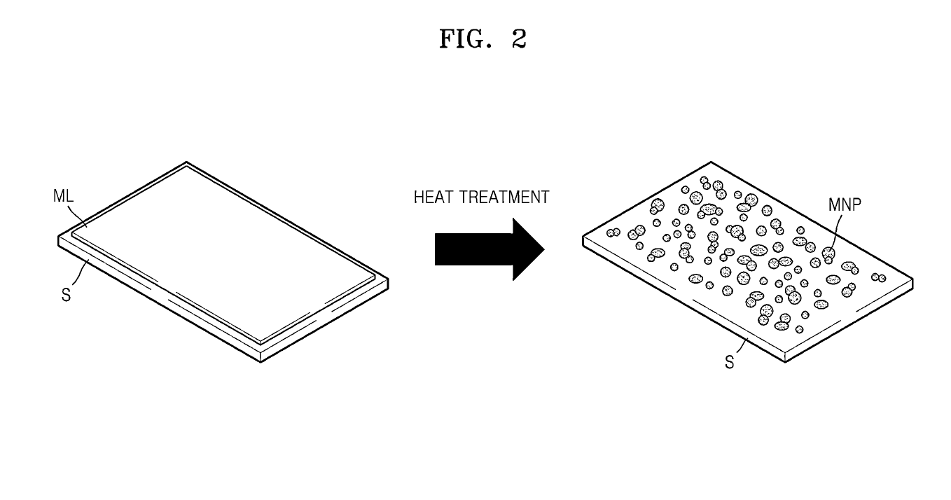

FIG. 2 is a diagram illustrating a dewetting process used in a method of manufacturing the 3D nanoplasmonic structure 100, according to an embodiment.

A thin metal film ML is formed on a substrate S, a heat treatment process is performed thereon, and the thin metal film ML is changed into a plurality of metal nanoparticles MNP. This is referred to as a dewetting process. If the thickness of the thin metal film ML and the dewetting temperature and time are appropriately determined, the size distribution of the metal nanoparticles MNP may be adjusted, thus permitting the adjustment of the surface plasmon resonance frequency.

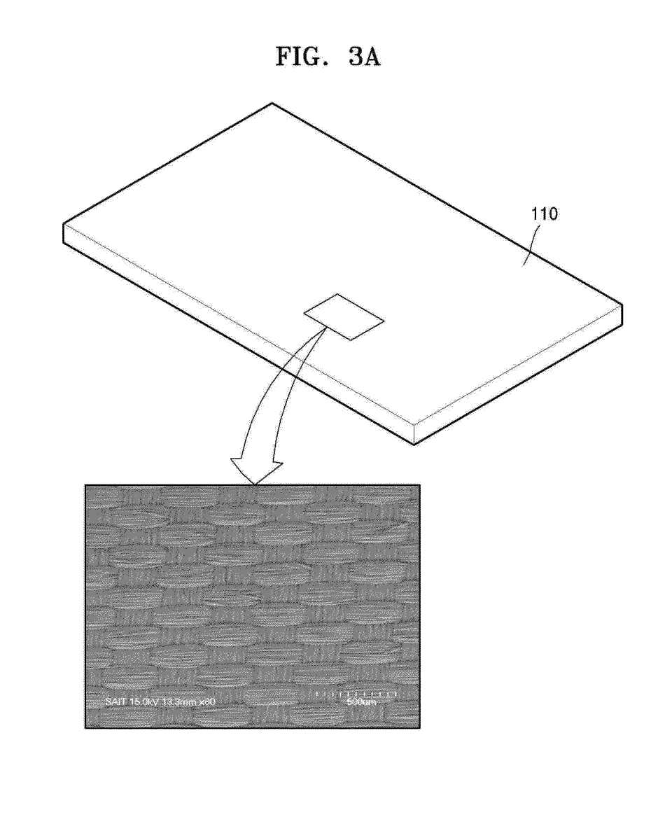

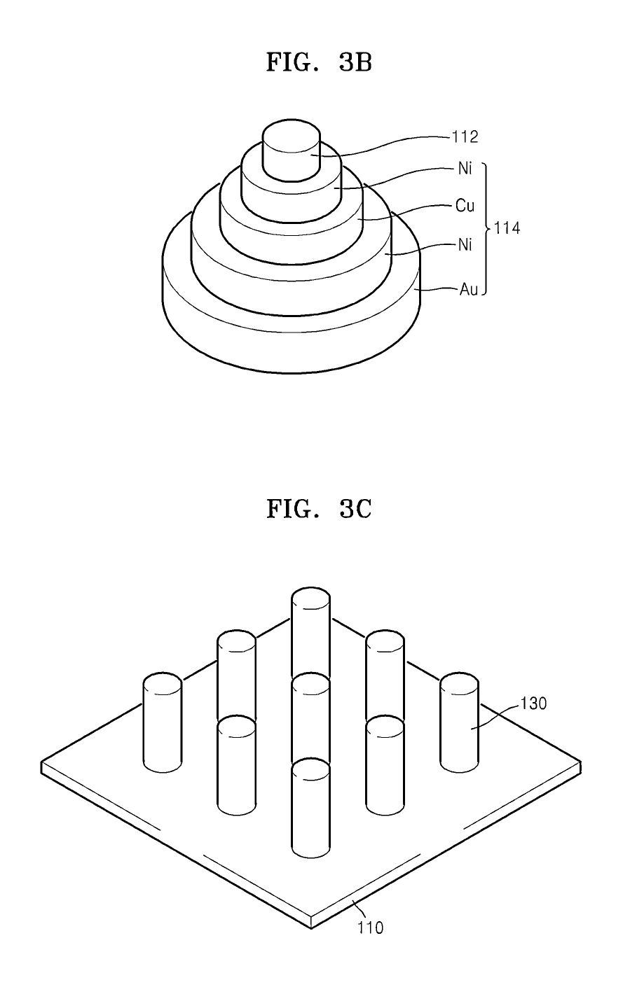

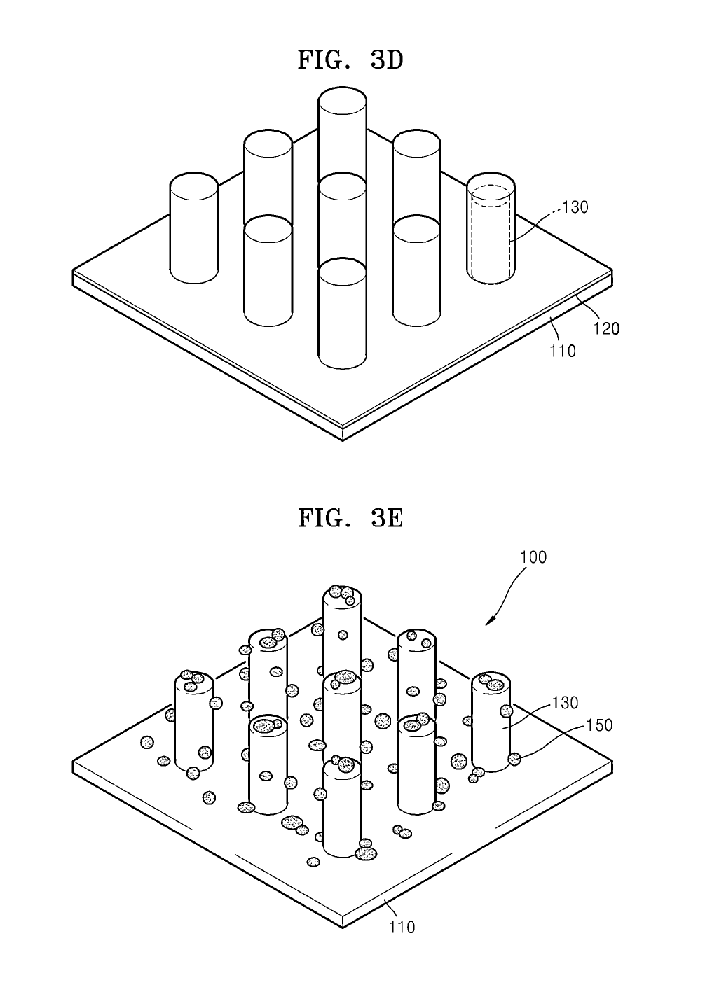

FIGS. 3A through 3E are diagrams illustrating a method of manufacturing the 3D nanoplasmonic structure 100, according to an embodiment.

FIGS. 3A and 3B are, respectively, a magnified view of a textile structure substrate as an example of the substrate 110, and a perspective view of an example when a conductive layer 114 is coated on a textile fiber 112.

The substrate 110 may include the textile fiber 112 formed from a flexible material, and a conductive layer 114 coated on the surface of the textile fiber 112. The textile fiber 112 may have a 2D shape in which a plurality of fiber strands are knitted to a certain pattern. The textile fiber 112 may include a polymer, such as polystyrene, polyester, or polyurethane.

The conductive layer 114 may be coated to cover the whole surface of the textile fiber 112. Here, the conductive layer 114 may be coated on the surface of the textile fiber 112 using, for example, an electroless plating method or a sputtering method. The conductive layer 114 may have a thickness of, for example, from about 100 nm to about 1 μm. However, the thickness is not particularly limited. The conductive layer 114 may include at least one metal layer. Here, the metal layer may include at least one of, for example, nickel (Ni), copper (Cu), and gold (Au) and, as illustrated in FIG. 3B, the conductive layer 114 may include, but is not limited to, a Ni layer, a Cu layer, another Ni layer, and a Au layer sequentially coated on the textile fiber 112 in this order.

Although a conductive textile structure is used as the substrate 110 in FIGS. 3A and 3B, the substrate 110 is not limited thereto and a carbon material textile structure or an inorganic material textile structure may be used. Also, a semiconductor substrate formed of Si, Ge, GaAs, or GaN, a polymer substrate formed from, for example, an organic polymer or an inorganic polymer, or a substrate formed from, for example, quartz or glass may be used.

Then, as illustrated in FIG. 3C, the nanorods 130 are formed on the substrate 110. The nanorods 130 may be formed from, for example, an oxide semiconductor material, a metal oxide, an insulating material, or carbon nanotubes. For example, the nanorods 130 may include at least one of ZnO, In₂O₃, Ga₂O₃, SnO, IZO, ITO, GIZO, HflnZnO, SnO₂, Co₃O₄, Mn₃O₄, MnO, Fe₂O₃, Fe₃O₄, NiO, MoO₃, MoO₂, TiO₂, CuO, Cu₂O, LiFePO₄, CeO₂, RuO₂, MnO₂, Li₄Ti₅O₁₂, and Li₃V₂(PO₄)₃, and may be in the form of nanowires or nanotubes.

The nanorods 130 may be grown using various methods appropriate for the type of the substrate 110 and the material used for the nanorods 130, such as, for example, a chemical vapor deposition (CVD) method or a hydrothermal method.

Then, as illustrated in FIG. 3D, a metal layer 120 is formed on the surface of the substrate 110 and the surfaces of the nanorods 130. The metal layer 120 may include at least one of Au, Ag, Ru, and Cu. The metal layer 120 may be formed using, for example, an electron beam (e-beam) deposition method, a thermal deposition method, an atomic layer deposition (ALD) method, or a sputtering method.

The thickness of the metal layer 120 may be determined based on the desired size distribution of metal nanoparticles to be formed by metal layer 120, and may be from about 10 nm to about 100 nm thick.

Metal nanorods formed as described above have an absorbance spectrum peak at a certain wavelength due to surface plasmon resonance. Also, the absorbance peak wavelength band varies according to the aspect ratio of the metal nanorods. For example, it is known that the peak wavelength band moves to a longer wavelength band if the aspect ratio is increased.

In the current embodiment, a dewetting process is performed on the above-described metal nanorods to move the peak wavelength band of the absorbance spectrum.

FIG. 3E shows the 3D nanoplasmonic structure 100 in which metal nanoparticles 150 have been formed on the surfaces of the nanorods 130 after a dewetting process has been performed.

The dewetting temperature may be, but is not limited to, from about 350° C. to about 700° C.

The dewetting time may be, but is not limited to, from about 1 hour to about 5 hours.

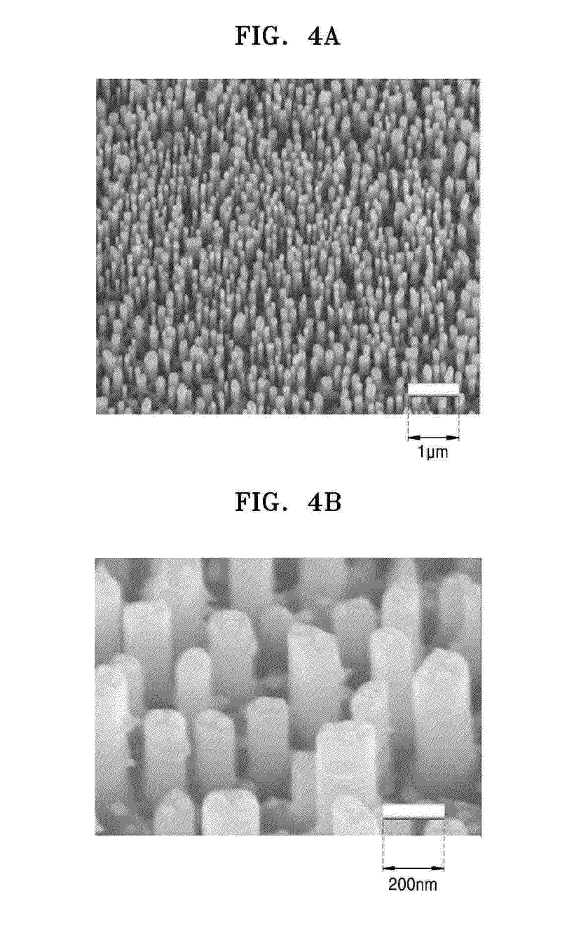

FIGS. 4A and 4B are microscopic images of a plurality of nanorods and a plurality of metal nanoparticles, respectively, formed using a method of manufacturing a 3D nanoplasmonic structure, according to an embodiment.

The specific process conditions behind these figures are described below.

ZnO was epitaxially grown on a GaN substrate formed on glass. In more detail, GaN was deposited on c-form aluminum oxide (c-Al₂O₃) using a metal organic chemical vapor deposition (MOCVD) method so as to have a thickness of 4 mm and, as a catalyst for growing ZnO, Au was deposited on GaN using a thermal evaporator so as to have a thickness of 2 nm. Then, ZnO nanorods were grown using a CVD method at 880° C. for 2 hours. FIG. 4A is a microscopic image of the resulting ZnO nanorods.

Then, Au was deposited on the ZnO nanorods and a dewetting process was performed. In more detail, a thin Au film was grown on the grown ZnO nanorods using a thermal evaporator so as to have a thickness of 10 nm or 20 nm, and was heat-treated at 650° C. for 3 hours. As such, the thin Au film was dewetted and thus Au nanoparticles were formed on the upper, lower, and side surfaces of the ZnO nanorods. FIG. 4B is a microscopic image of these Au nanoparticles.

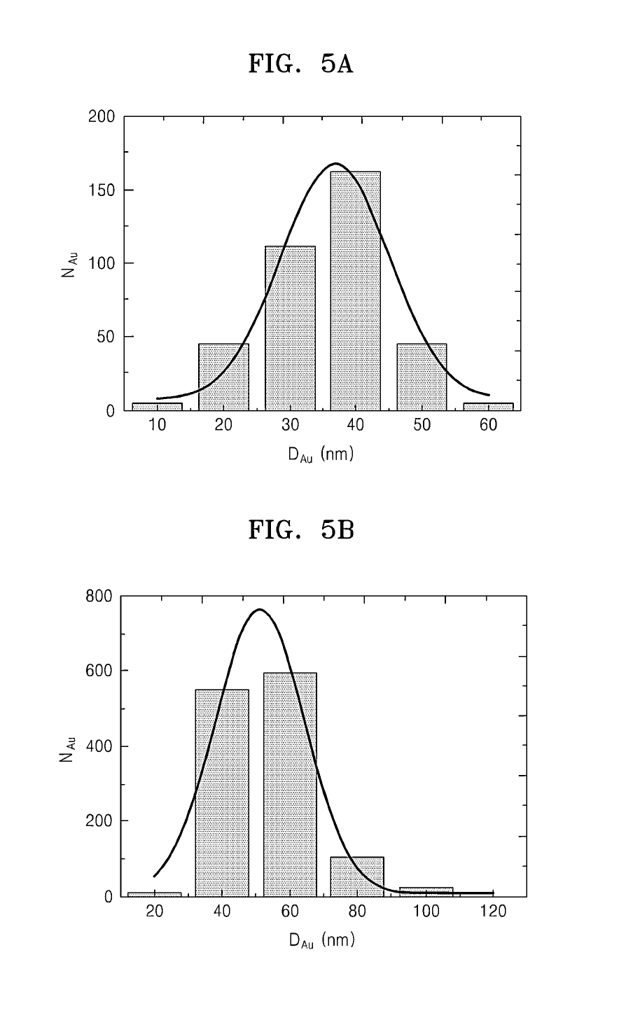

FIGS. 5A and 5B are graphs showing the size distributions of metal nanoparticles formed from a given thickness of a thin Au film in a method of manufacturing a 3D nanoplasmonic structure, according to an embodiment.

FIG. 5A shows the case when the thin Au film is formed so as to have a thickness of 10 nm. D_{Au} indicates the diameter of Au nanoparticles, and N_{Au} indicates the number of Au nanoparticles. The average diameter of the plurality of Au nanoparticles is about 36 nm.

FIG. 5B shows the case when the thin Au film is formed so as to have a thickness of 20 nm. The average diameter of the plurality of Au nanoparticles is about 52 nm.

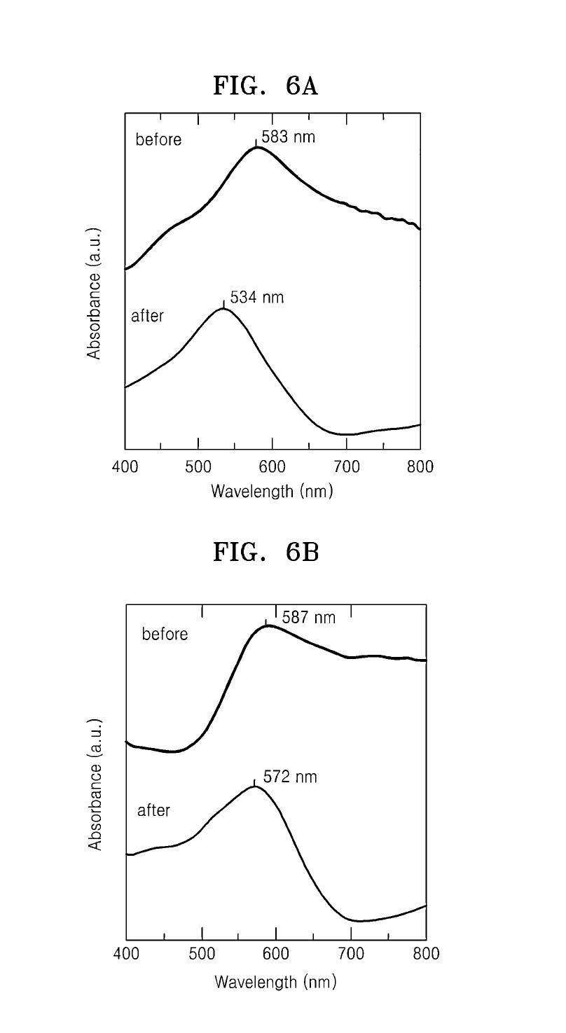

FIGS. 6A and 6B are graphs showing absorbance spectra formed before and after heat treatment is performed in a method of manufacturing a 3D nanoplasmonic structure, respectively regarding different thicknesses of a thin Au film, according to an embodiment.

FIG. 6A shows the case when the thin Au film is formed so to have a thickness of 10 nm, and FIG. 6B shows the case when the thin Au film is formed so as to have a thickness of 20 nm. These figures illustrate that after the dewetting process, a peak wavelength moves to a shorter wavelength band.

The above test result shows that the peak wavelength of an absorbance spectrum moves as the result of a dewetting process that changes a thin Au film into particles.

The above-described 3D nanoplasmonic structure has a high optical absorption rate as a result of a plasmonic effect and has an increased active region as a result of its 3D structure.

The above-described 3D nanoplasmonic structure may be used in various optoelectronic devices, such as an optical biosensor, a light-emitting device, and an energy storing device, such as a solar battery or a secondary battery.

In the above-described method of manufacturing a 3D nanoplasmonic structure, a plurality of metal nanoparticles may be formed and the peak wavelength band of an optical absorbance spectrum may be adjusted by using a dewetting process.

It should be understood that the exemplary embodiments described therein should be considered to be descriptive only and not limiting. Descriptions of features or aspects within each embodiment should be understood as being available for other similar features or aspects in other embodiments.

What is claimed is:

1. A three-dimensional (3D) nanoplasmonic structure comprising:
a substrate;
a plurality of nanorods formed on the substrate; and
a plurality of metal nanoparticles formed on surfaces of the substrate and the plurality of nanorods.

2. The 3D nanoplasmonic structure of claim 1, wherein the plurality of nanorods comprise an oxide semiconductor material, a metal oxide, an insulating material, or carbon nanotubes.

3. The 3D nanoplasmonic structure of claim 1, wherein the plurality of metal nanoparticles comprise one of gold (Au), silver (Ag), ruthenium (Ru), and copper (Cu).

4. The 3D nanoplasmonic structure of claim 1, wherein the plurality of metal nanoparticles have a size distribution of at least two sizes.

5. The 3D nanoplasmonic structure of claim 1, wherein the substrate comprises a textile structure.

6. The 3D nanoplasmonic structure of claim 5, wherein the textile structure comprises textile fiber and a conductive layer coated on a surface of the textile fiber.

7. The 3D nanoplasmonic structure of claim 5, wherein the substrate comprises a carbon material textile or an inorganic material textile.

8. An optoelectronic device comprising the 3D nanoplasmonic structure of claim 1.

9. A method of manufacturing a three-dimensional (3D) nanoplasmonic structure, the method comprising:
preparing a substrate;
forming a plurality of nanorods on the substrate;
forming a metal layer on surfaces of the plurality of nanorods; and
dewetting the metal layer into particles by heat-treating the metal layer.

10. The method of claim 9, wherein the plurality of nanorods comprise an oxide semiconductor material, a metal oxide, an insulating material, or carbon nanotubes.

11. The method of claim 9, wherein the forming the plurality of nanorods comprises using a chemical vapor deposition method or a hydrothermal method.

12. The method of claim 9, wherein the metal layer comprises one of gold (Au), silver (Ag), ruthenium (Ru), and copper (Cu).

13. The method of claim 9, wherein the forming the metal layer comprises using an electron beam deposition method, a thermal deposition method, an atomic layer deposition method, or a sputtering method.

14. The method of claim 9, wherein the forming the metal layer comprises forming the metal layer in a thickness of from about 10 nm to about 100 nm.

15. The method of claim 9, wherein a dewetting temperature of the dewetting is from about 350° C. to about 700° C.

16. The method of claim 9, wherein a dewetting time of the dewetting is from about 1 hour to about 5 hours.

17. The method of claim 9, wherein the substrate is a textile structure.

18. The method of claim 17, wherein the textile structure comprises a textile fiber and a conductive layer coated on a surface of the textile fiber.

19. The method of claim 9, wherein the substrate comprises a carbon material textile structure or an inorganic material textile structure.

20. A method of adjusting a surface plasmon resonance frequency, the method comprising:
forming a surface plasmon resonance structure; and
dewetting a metal material included in the surface plasmon resonance structure.

21. The method of claim 20, wherein the surface plasmon resonance structure comprises a plurality of nanorods and a metal layer formed on a surface of the plurality of nanorods.

22. The method of claim 21, wherein the metal layer has a thickness from about 10 nm to about 100 nm.

23. The method of claim 20, wherein a dewetting temperature of the dewetting is from about 350° C. to about 700° C.

24. The method of claim 20, wherein a dewetting time of the dewetting is from about 1 hour to about 5 hours.

25. The 3D nanoplasmonic structure of claim 6, wherein the conductive layer comprises a layer of Ni, a layer of Cu, a layer of Ni, and a layer of Au successively coated on the textile fiber.

26. The method of claim 18, wherein the conductive layer comprises a layer of Ni, a layer of Cu, a layer of Ni, and a layer of Au successively coated on the textile fiber.
